(19) United States
(12) Patent Application Publication
(10) Pub. No.: US 2015/0181701 A1
(43) Pub. Date: Jun. 25, 2015

(54) CHIP ON FILM MODULE, DISPLAY PANEL AND DISPLAY

(71) Applicant: SHENZHEN CHINA STAR OPTOELECTRONICS TECHNOLOGY CO., LTD., Shenzhen (CN)

(72) Inventor: Houbin Li, Shenzhen (CN)

(21) Appl. No.: 14/241,713

(22) PCT Filed: Jan. 17, 2014
(86) PCT No.: PCT/CN2014/070755

§ 371 Date: Feb. 27, 2014

(30) Foreign Application Priority Data
Dec. 25, 2013 (CN) 201310728633.X

(51) Int. Cl. H05K 1/02; H05K 1/03; H05K 1/18

(52) U.S. Cl. CPC H05K 1/0296; H05K 1/189; H05K 1/0393; H05K 2201/10128

(57) ABSTRACT

The present disclosure disclosed a chip on film module of display panel, comprising: a flexible substrate, a chip arranged on the flexible substrate, and a first group of terminals, wherein, each of the first group of terminals comprises a metal bonding section with different area for contacting with a fan-out terminal of a corresponding fan-out wire of the display panel, so that the equivalent resistance on each fan-out wire is equal or approximate. The present disclosure also provides a display panel, comprising: a display unit; and a group of fan-out terminals connected with the display unit, wherein each of the fan-out terminals comprises metal bonding section with different area used for contacting with a corresponding one of the first group of terminals of a chip on film (COF) module. The present disclosure can effectively eliminate the color cast caused by the non-uniformity of the impedances on the fan-out wires.

### FIELD OF THE INVENTION

The present disclosure relates to the field of display technologies, and particularly, to a chip on film module, a display panel, and a display.

### BACKGROUND OF THE INVENTION

With the popularization of mobile electronic products and large screen displays, low-cost, high-density and massive electronic production technologies have been rapidly developed. Both large-size electronic products such as liquid crystal displays, liquid crystal televisions and plasma televisions, and small-size electronic products such as mobile phones and digital cameras, which tend to be light, thinness, and compact, require a new generation of packaging technologies for high density and small volume, and capable of realizing free installation to meet the needs above. A COF (Chip On Flex, or Chip On Film) packaging technology is emerged in this circumstance. The technology is a crystal grain flexible film packaging technology, by which a chip is fixed on a flexible circuit board. The flexible circuit board is used as a packaging chip carrier for engaging the chip with a flexible substrate circuit.

However, in particular, in a single-source COF product, due to the limitation of a fan-out design on the liquid crystal display panel (Cell), wires at the both sides of the panel are longer than those at the middle, as shown in FIG. 1. Therefore, the fan-out impedances of wires at the both sides are greater than the fan-out impedances of wires at the middle, as shown in FIG. 2. In the case that an electric signal is applied to the liquid crystal display panel (Cell) to drive it, the non-uniformity of the fan-out impedances of the Cell causes a color cast phenomenon of the liquid crystal display panel, as shown in FIG. 3.

Therefore, there is a need to provide a COF module or a display panel which can eliminate the non-uniformity of the Fan-out impedances, so as to improve the display quality of the display panel.

### SUMMARY OF THE INVENTION

In order to solve the above-mentioned technical problems, the present disclosure provides a chip on film module, comprising: a flexible substrate, a chip arranged on the flexible substrate, and a first group of terminals arranged on the flexible substrate and electrically connected with an output end of the chip, wherein each of the first group of terminals comprises a metal bonding section with different area for contacting with a fan-out terminal of a corresponding fan-out wire of the display panel, so that the equivalent resistance on each fan-out wire is equal or approximate.

According to an embodiment of the present disclosure, the metal bonding sections on the first group of terminals each have the same width, but have an area that is set to be related to the length of the corresponding fan-out wire on the display panel.

According to an embodiment of the present disclosure, the area of the metal bonding section is gradually increased in sequence from the terminal at the middle position to the terminals at the both sides, and wherein the contact area of the metal bonding section on the terminal at the middle position in the first group of terminals is minimal.

According to an embodiment of the present disclosure, the chip on film module further comprises a second group of terminals used for connecting an input end of the chip on film module with a drive circuit board.

According to another aspect of the present disclosure, there is provided a display panel, comprising: a display unit on which a plurality of pixel arrays are arranged; and a group of fan-out terminals connected with the display unit, wherein each of the fan-out terminals comprises metal bonding section with different area used for contacting with a corresponding one of the first group of terminals of a chip on film module, so that the equivalent resistance on each fan-out wire is equal or approximate.

According to an embodiment of the present disclosure, the area of the metal bonding section on each of the fan-out terminals is set to be related to the length of the corresponding fan-out wire, so that the equivalent resistance on each of fan-out wires is equal or approximate.

According to an embodiment of the present disclosure, the area of the metal bonding section is gradually increased in sequence from the terminal at the middle position to the terminals at the both sides, and wherein the contact area of the metal bonding section on the terminal at the middle position in the fan-out terminals is the minimum.

According to another aspect of the present disclosure, a display is further provided, wherein the display comprises the above-mentioned chip on film module.

According to yet another aspect of the present disclosure, a display is further provided, comprising the above-mentioned display panel.

According to yet another aspect of the present disclosure, there is further provided a display, comprising the above-mentioned chip on film module and the above-mentioned display panel, wherein the output terminal of the chip on film module is in bonding connection with a corresponding one of fan-out terminals of the display panel by virtue of an ACF (anisotropic conductive film) process, so that equivalent resistance on each of fan-out wires is equal or approximate.

The chip on film module, the display panel, and the display designed according to the principle of the present disclosure can effectively eliminate the color cast phenomenon caused by the non-uniformity of the impedances on the fan-out wires in the previous design. Moreover, the impedance limitation of fan-out areas at a source side during the design can be extended. In this case, the heights of the fan-out terminals can be compressed to a greater extent, and thus being more favorable for a design of the panel with a narrow frame.

Other features and advantages of the present disclosure will be illustrated in the following description, and are partially obvious from the description or understood through implementing the present disclosure. The objectives and other advantages of the present disclosure may be realized and obtained through the structures specified in the description, claims and accompanying drawings.

### BRIEF DESCRIPTION OF THE DRAWINGS

The accompanying drawings are provided for further understanding of the present disclosure, constitute a part of the description, and are used for interpreting the present disclosure together with the embodiments of the present disclosure, rather than limiting the present disclosure. In the accompanying drawings:

FIG. 1 shows a schematic diagram of position relationship between a single-source COF display module and a Cell display panel in the Cell manufacturing procedures of the prior art;

FIG. 2 shows a distribution graph of impedances on fan-out wires in a Cell in the prior art;

FIG. 3 shows a color cast phenomenon caused due to the difference of fan-out impedances in the prior art;

FIG. 4 shows a structure schematic diagram of the configuration of a display;

FIG. 5 shows a schematic diagram of realizing bonding contact between the output terminal of a COF and the wiring terminal of a Cell by virtue of an ACF process in the prior art;

FIG. 6a shows a schematic diagram of the changes of the bonding area of a COF side according to an embodiment of the present disclosure;

FIG. 6b shows a schematic diagram of the changes of the bonding area of a Cell display panel side according to an embodiment of the present disclosure; and

FIG. 6c shows a schematic diagram of changes of both the bonding area of a COF module side and the bonding area of a Cell display panel side according to an embodiment of the present disclosure.

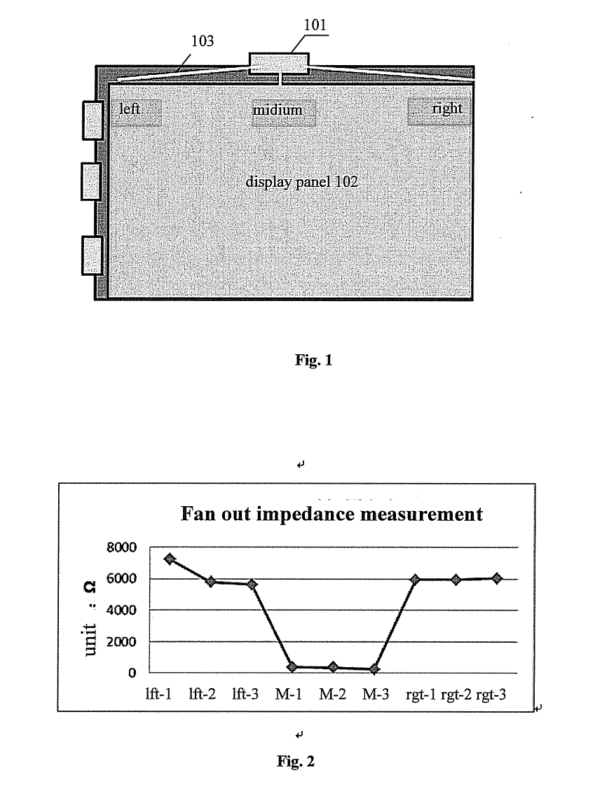

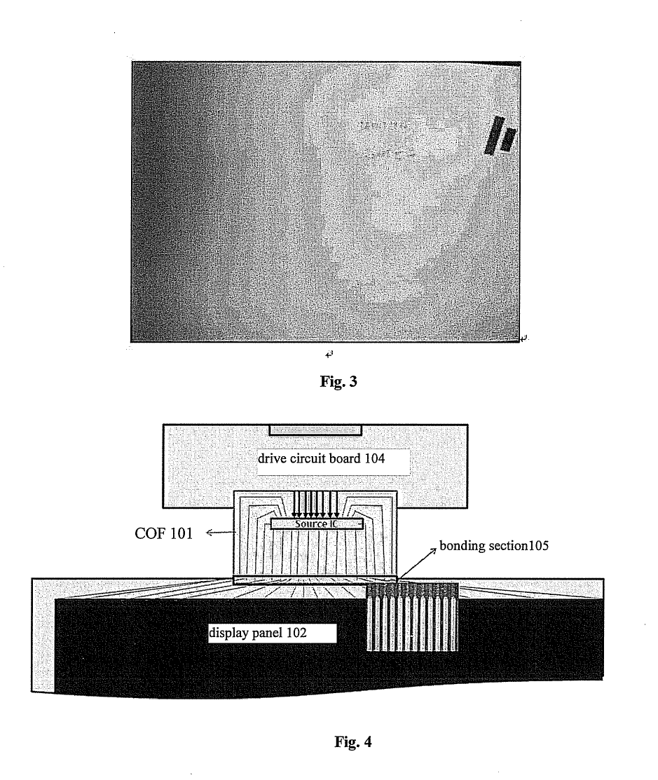

### DETAILED DESCRIPTION OF THE EMBODIMENTS

The embodiments of the present disclosure will be illustrated in detail in conjunction with the accompanying drawings and examples, and thus how to solve the technical problems by technical means and the implementation process of achieving the technical effects may be fully understood and accordingly implemented. It should be noted that as long as conflicts are avoided, each embodiment in the present disclosure and each feature thereof may be combined with each other, as long as they do not conflict, and the technical solutions formed thereby are within the scope of the present disclosure.

FIG. 4 shows a structure schematic diagram of the configuration of a display. The display comprises a drive circuit board 104, a COF display module 101, and a Cell display panel 102. In the phase of Cell manufacturing procedures, the COF display module 101 is connected with the Fan-out terminals of the Cell display panel 102 by virtue of metal bonding section 105 on the output terminals (for example, golden finger structures) of the COF display module, to transmit the electric drive signal of the drive circuit board 104 to each display unit in the Cell display panel, so that a corresponding color is displayed as expected.

In the prior art, the influence of the non-uniformity of impedance distribution from the middle to the both sides caused by the length difference of the wires of the fan-out wires at the Cell side is not considered. Therefore, the area of the metal bonding section where the COF side is in contact with the Cell side is set to equal. In this case, a color cast phenomenon occurs.

In order to reduce and even eliminate the problem of the non-uniformity of impedances on the fan-out wires, the present disclosure provides a COF display module, comprising: a flexible substrate, a chip IC arranged on the flexible substrate, and a group of terminals arranged on the flexible substrate and electrically connected with an output end of the chip, wherein, each of the group of terminals includes metal bonding section 105 with different area for contacting with ta fan-out terminal of a corresponding fan-out wire of a display panel, so that equivalent resistance on each of fan-out wires is equal or approximate. The area of the metal bonding section 105 on a part of the adjacent or centrosymmetric terminals may be equal. Because as long as the terminal has the metal bonding section 105 with different area, the problem of non-uniform impedances can be reduced, and the present disclosure can be implemented.

The contact area of the metal bonding section 105 on each of the group of terminals can be set according to the length of the fan-out wire on the display panel, so that equivalent resistance on each of fan-out wire is uniform. Alternatively or optionally, the equivalent resistance on each of the fan-out wire wire may be different in a certain range which can be determined according to actual conditions.

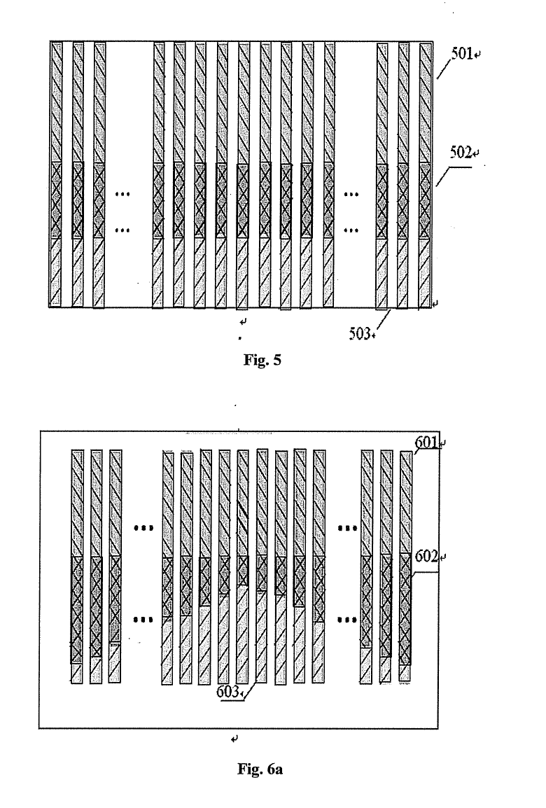

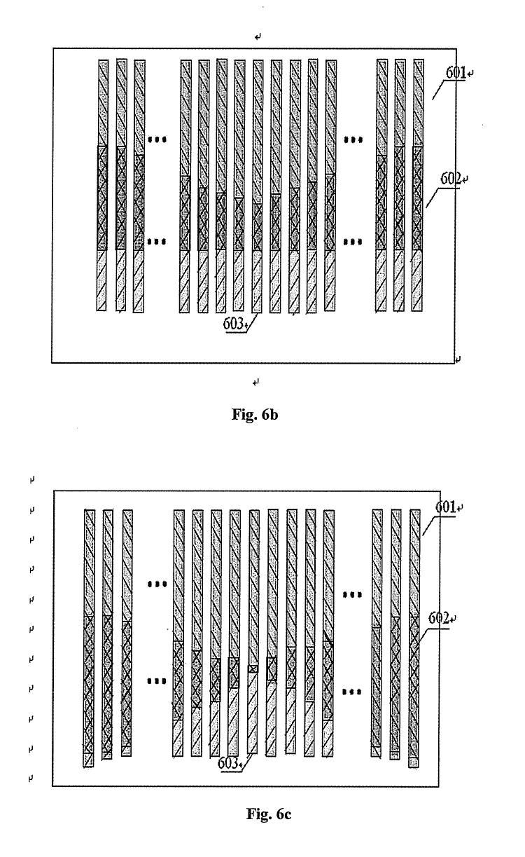

The contact area of the metal bonding section 105a of the COF module 101 is gradually increased in sequence from the terminal at the middle position to the terminals at the both sides so that equivalent resistance on each of fan-out wire is substantially equal, wherein the contact area of the metal bonding section 105 on the terminal at the middle position is the minimum. As shown in FIG. 6a, the distribution of the area of the metal bonding section 602 on the terminal 601 at the COF side is dovetail-shaped, which is bonded with the terminal 603 at the Cell side by virtue of the ACF process.

The COF module 101 according to the present disclosure further comprises another group of terminals for connecting an input end of the chip in the COF module with the drive circuit board 104, so as to receive a drive electric signal on the drive circuit.

According to the principle of the present disclosure, a Cell display panel 102 is further provided, comprising: a display unit on which a plurality of pixel arrays are arranged; and a group of fan-out terminals connected with the display unit, wherein each of the fan-out terminals includes a metal bonding section with different area for correspondingly contacting with one group of terminals of the COF display module 101, so that equivalent resistance on each of the fan-out wires is equal or approximate.

The contact area of the metal bonding section on each of the fan-out terminals of the Cell display panel 102 is set to be related to the length of the corresponding fan-out wire, so that equivalent resistance on each of fan-out wire is uniform.

As shown in FIG. 6b, the contact area of the metal bonding section 602 is gradually increased in sequence from the terminal at the middle position to the terminals at the both sides, wherein, the contact area of the metal bonding section 602 on the terminal at the middle position in the fan-out terminals is the minimum. As shown in FIG. 6b, the distribution of the area of the metal bonding section 602 on the terminal 603 at the Cell side is dovetail-shaped, and the terminal 603 is bonded with the terminal 601 at the COF side by virtue of the ACF process.

The area of the metal bonding section of the COF module and the Cell display panel can be designed to be in the form of being gradually increased in sequence from the terminal at the middle position to the terminals at the both sides, so that equivalent resistance on each of the fan-out wires is uniform, approximately equal and the like respectively. As shown in FIG. 6c, the both sides of each bonding section are dovetail-shaped.

The present disclosure further provides a display, comprising the above-mentioned COF module.

The present disclosure further provides a display, comprising the above-mentioned Cell display panel.

The present disclosure further provides a display, comprising the above-mentioned COF module and the above-mentioned display panel, wherein the output terminal of the COF display module is in bonding connection with a corresponding one of fan-out terminals of the Cell display panel by virtue of an ACF (anisotropic conductive film) process.

Although the embodiments are described above, the foregoing are merely the embodiments for facilitating the understanding of the present disclosure, rather than limiting the present disclosure. Any changes or alternatives conceived by the skilled ones in the art after reading the content disclosed herein will fall within the scope of the present disclosure. Accordingly, the scope of the present disclosure will be defined in the accompanying claims.

1. A chip on film module of display panel, comprising:
a flexible substrate,
a chip arranged on the flexible substrate, and
a first group of terminals, arranged on the flexible substrate and electrically connected with an output end of the chip,
wherein each of the first group of terminals comprises a metal bonding section with different area for contacting with a fan-out terminal of a corresponding fan-out wire of the display panel.

2. The chip on film module according to claim 1, wherein the metal bonding sections on the first group of terminals each have the same width, but an area that is set to be related to the length of the corresponding fan-out wire on the display panel.

3. The chip on film module according to claim 2, wherein the area of the metal bonding section is gradually increased in sequence from the terminal at the middle position to the terminals at the both sides, and wherein the contact area of the metal bonding section on the terminal at the middle position in the first group of terminals is minimal.

4. The chip on film module according to claim 1, wherein the chip on film module further comprises a second group of terminals for connecting an input end of the chip on film module with a drive circuit board.

5. A display panel, comprising:
a display unit, with a plurality of pixel arrays being arranged thereon; and
a group of fan-out terminals connected with the display unit, wherein each of the fan-out terminals comprises a metal bonding section with different area for contacting with a corresponding one of the first group of terminals of a chip on film module.

6. The display panel according to claim 5, wherein the area of the metal bonding section on the fan-out terminal is set to be related to the length of the corresponding fan-out wire.

7. The display panel according to claim 6, wherein the area of the metal bonding section is gradually increased in sequence from the terminal at the middle position to the terminals at the both sides, and wherein the contact area of the metal bonding section on the terminal at the middle position in the fan-out terminals is the minimum.

8. A display comprising a chip on film module, wherein the module comprises:
a flexible substrate,
a chip arranged on the flexible substrate, and
a first group of terminals, arranged on the flexible substrate and electrically connected with an output end of the chip, wherein each of the first group of terminals comprises a metal bonding section with different area for contacting with a fan-out terminal of a corresponding fan-out wire of a display panel.

9. The display according to claim 8, wherein the metal bonding sections on the first group of terminals each have the same width, but have an area that is set to be related to the length of the corresponding fan-out wire on the display panel.

10. The display according to claim 9, wherein the area of the metal bonding section is gradually increased in sequence from the terminal at the middle position to the terminals at the both sides, and wherein the contact area of the metal bonding section on the terminal at the middle position in the first group of terminals is minimal.

11. The display according to claim 8, wherein the module further comprises a second group of terminals for connecting an input end of the chip on film module to a drive circuit board.

12. The display according to claim 8, wherein the display panel comprises:
a display unit on which a plurality of pixel arrays are arranged; and
a group of fan-out terminals connected with the display unit, wherein each of the fan-out terminals comprises a metal bonding section with different area used for contacting with a corresponding one of the first group of terminals of the chip on film module.

13. The display according to claim 12, wherein the area of the metal bonding section on each of the fan-out terminals is set to be related to the length of the corresponding fan-out wire.

14. The display according to claim 13, wherein the area of the metal bonding section is gradually increased in sequence from the terminal at the middle position to the terminals at the both sides, and wherein the contact area of the metal bonding section on the terminal at the middle position in the fan-out terminals is the minimum.
